(19) United States
(12) Patent Application Publication
(10) Pub. No.: US 2026/0043139 A1
(43) Pub. Date: Feb. 12, 2026

(54) THIN FILM DEPOSITION APPARATUS

(71) Applicant: Samsung Display Co., LTD., Yongin-si (KR)

(72) Inventors: CHOELMIN JANG, Yongin-si (KR); DOHUN PARK, Yongin-si (KR); MIN-GYU PARK, Yongin-si (KR); HEEYONG LEE, Yongin-si (KR)

(21) Appl. No.: 19/180,689

(22) Filed: Apr. 16, 2025

(30) Foreign Application Priority Data
Aug. 9, 2024 (KR) 10-2024-0106558

(51) Int. Cl. C23C 16/455; C23C 16/50

(52) U.S. Cl. CPC C23C 16/45574; C23C 16/45591; C23C 16/50

(57) ABSTRACT

A thin film deposition apparatus includes: a support, which supports a substrate; and a spray unit including a first spray section and a second spray section arranged along a first direction parallel to a major surface of the support. In the spray unit, the first spray section is configured to spray a source gas onto one surface of the substrate and exhaust the source gas, and the second spray section is configured to spray a reaction gas onto the one surface of the substrate and form a plasma. The reaction gas sprayed from the second spray section flows over the one surface of the substrate and is exhausted through the first spray section.

This application claims priority to Korean Patent Application No. 10-2024-0106558, filed on Aug. 9, 2024, and all the benefits accruing therefrom under 35 U.S.C. § 119, the content of which in its entirety is herein incorporated by reference.

### BACKGROUND

### 1. Technical Field

The present disclosure relates to a thin film deposition apparatus, specifically to a thin film deposition apparatus using a spatially separated deposition technique.

### 2. Description of the Related Art

In general, methods for depositing a thin film of a predetermined thickness on a substrate include physical vapor deposition (PVD), which utilizes physical collisions, such as sputtering, and chemical vapor deposition (CVD), which uses chemical reactions.

Conventional CVD involves injecting multiple reaction gases into a chamber simultaneously to deposit generated reaction products onto the substrate. However, when injecting reaction gases simultaneously into the chamber using the CVD method, there is a higher likelihood of particle generation due to reactions not only on the substrate surface but also above the substrate, and the deposition rate may exceed 100 nm/min, making it difficult to form a dense thin film.

As a solution, atomic layer deposition (ALD) has been developed to minimize particle generation and enable the formation of dense thin films. In spatially separated atomic layer deposition (ALD), thin films such as metal oxides are deposited on the substrate by spatially separating and spraying a source gas and a reaction gas through a linear deposition source that includes multiple linear nozzles.

In the conventional spatially separated ALD, the source gas and the reaction gas are separated by an air curtain. However, due to various factors, the air curtain fails to adequately separate the source gas from the reaction gas, resulting in gas mixing issues.

### SUMMARY

The present disclosure aims to provide a spatially separated thin film deposition apparatus to prevent a source gas and a reaction gas from mixing with each other.

According to one aspect of the present disclosure, there is provided a thin film deposition apparatus including a support, which supports a substrate; and a spray unit including a first spray section and a second spray section arranged along a first direction parallel to a major surface of the support. In the spray unit, the first spray section is configured to spray and exhaust a source gas onto one surface of the substrate, and the second spray section is configured to spray a reaction gas and form a plasma on the one surface of the substrate. The reaction gas sprayed from the second spray section may flow over the one surface of the substrate and be exhausted through the first spray section.

The spray unit may further include a partition wall separating the first spray section from the second spray section, wherein the reaction gas sprayed from the second spray section may flow through a gap between the one surface of the substrate and the partition wall to be exhausted through the first spray section. The partition wall may be configured to maintain the plasma within the second spray section.

Moreover, the reaction gas sprayed from the second spray section may purge in the gap between the one surface of the substrate and the partition wall. The first spray section may include a first spray nozzle configured to spray the source gas and an exhaust pipe configured to discharge the source gas sprayed from the first spray nozzle along with the reaction gas flowed in from the second spray section.

The support may be configured to transport the substrate in the first direction. The spray unit may be configured to move in the first direction. The spray unit may include the first spray section in plurality and the second spray section in plurality, and the plurality of first spray section and the plurality of second spray sections may be arranged alternately along the first direction. Moreover, the second spray sections may be provided in at least one pair, and the first spray section may be disposed between the at least one pair of the second spray sections.

The spray unit may further include a spacing adjustment mechanism configured to adjust the distance between the spray unit and the substrate in a second direction normal to the major surface of the support. The spacing adjustment mechanism may have a tilting function to incline the spray unit relative to the substrate.

According to another aspect of the present disclosure, provided is a thin film deposition apparatus including a support, which supports a substrate; and a spray unit including a first spray section, a third spray section, and a second spray section arranged along a first direction parallel to a major surface of the support. In the spray unit, the first spray section is configured to spray and exhaust a source gas onto one surface of the substrate, the second spray section is configured to spray a reaction gas onto the one surface of the substrate and form a plasma, and the third spray section is disposed between the first and second spray sections and configured to spray a doping gas onto the one surface of the substrate and exhaust the doping gas. The reaction gas sprayed from the second spray section may flow over the one surface of the substrate and be exhausted through the third spray section.

The spray unit may further include a fourth spray section disposed between the first and third spray sections and configured to spray a purge gas onto the one surface of the substrate. The purge gas sprayed from the fourth spray section may flow over the one surface of the substrate and be exhausted through the first and third spray sections. The reaction gas sprayed from the second spray section and the purge gas sprayed from the fourth spray section may be the same gas.

Moreover, the second spray sections may be provided in at least one pair, and the first spray section, the third spray section, and the fourth spray section may be disposed between the at least one pair of the second spray sections. In the spray unit, the first spray section may be configured to exhaust the reaction gas sprayed from the second spray section and the purge gas sprayed from the fourth spray section. Moreover, in the spray unit, the third spray section may be configured to exhaust the reaction gas sprayed from the second spray section and the purge gas sprayed from the fourth spray section.

Moreover, the third spray section may include a third spray nozzle configured to spray a doping gas and an exhaust pipe configured to discharge the doping gas sprayed from the third spray nozzle and the reaction gas flowed in from the second spray section. The spray unit may further include a partition wall separating the third spray section from the second spray section, and the reaction gas sprayed from the second spray section may flow through a gap between the one surface of the substrate and the partition wall to be exhausted through the third spray section. The reaction gas sprayed from the second spray section may purge in the gap between the one surface of the substrate and the partition wall.

According to one embodiment of the present disclosure, since the reaction gas performs a purging action of displacing and discharging the source gas, a path through which the source gas flows into a reaction region is fundamentally blocked, thereby possibly preventing the issue of the reaction gas mixing with the source gas in the reaction region.

Moreover, it is possible to eliminate additional configurations required for purging and air curtains and to skip any additional exhaust configuration for discharging the reaction gas.

### BRIEF DESCRIPTION OF THE DRAWINGS

These and/or other features will become apparent and more readily appreciated from the following description of the embodiments, taken in conjunction with the accompanying drawings in which:

FIG. 1 is a diagram illustratively showing a thin film deposition apparatus according to one embodiment of the present disclosure;

FIGS. 2 and 3 are diagrams for illustrating the operation of the thin film deposition apparatus according to one embodiment of the present disclosure;

FIGS. 4 to 8 are diagrams illustrating how a thin film is formed by the thin film deposition apparatus according to one embodiment of the present disclosure; and

FIG. 9 is a diagram illustratively showing a thin film deposition apparatus according to another embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings. The term “and/or” shall include the combination of a plurality of listed items or any of the plurality of listed items that can be defined by relevant elements.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

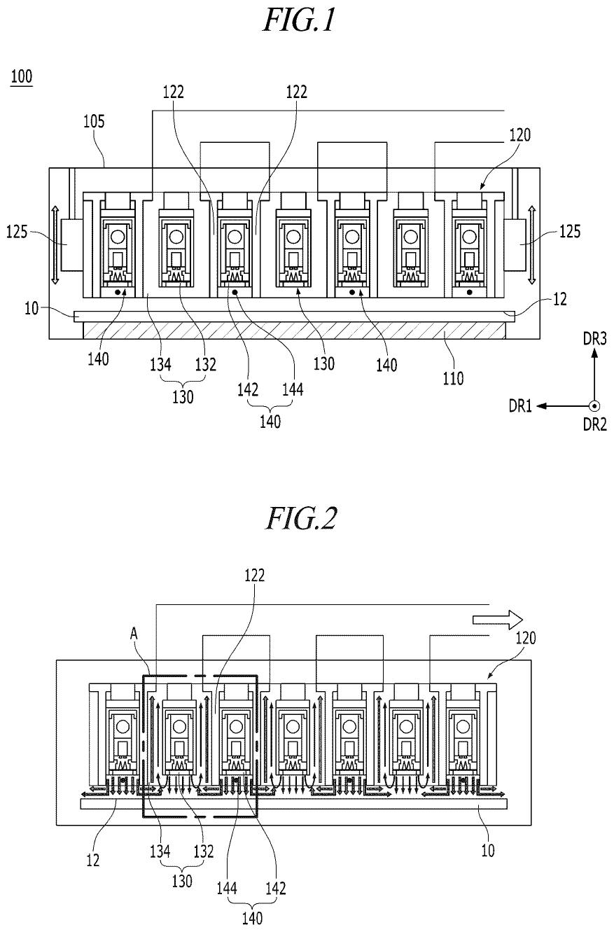

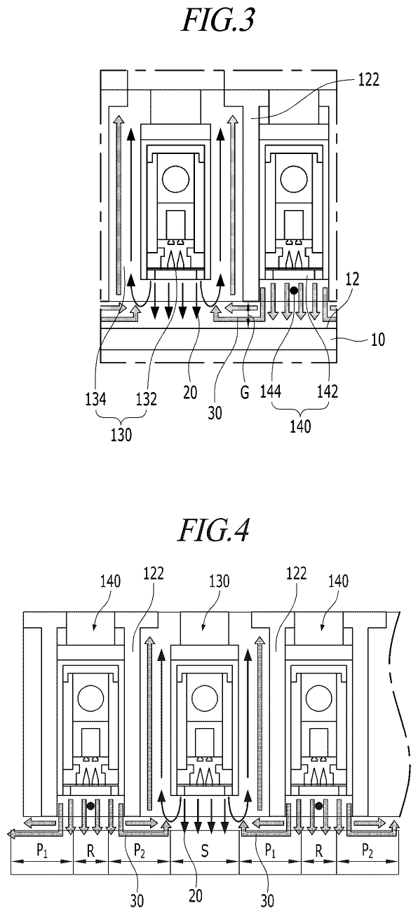

FIG. 1 is a diagram illustratively showing a thin film deposition apparatus according to one embodiment of the present disclosure, and FIGS. 2 and 3 are diagrams illustrating the operation of the thin film deposition apparatus according to one embodiment. FIG. 3 is an enlarged view of portion A in FIG. 2.

Referring to FIGS. 1 and 2, a thin film deposition apparatus 100 according to one embodiment of the present disclosure includes a support 110 and a spray unit 120. The support 110 supports a substrate 10. Referring to FIG. 1, in the present embodiment, to allow a thin film to be formed on one surface 12 (front surface or upper surface) of the substrate 10, the support 110 may support the opposite surface of the substrate 10.

In the present embodiment, the substrate 10 may have a flat structure and may be rectangular in shape in a view from above, with sides extending along a first direction DR1 and a second direction DR2 intersecting the first direction DR1. The substrate 10 may be provided with one surface 12 parallel to a plane defined by the first direction DR1 and the second direction DR2. A third direction DR3 is oriented toward the one surface 12 of the substrate 10 and may be parallel to the normal direction to the one surface 12 of the substrate 10.

The spray unit 120 is configured to spray a gas and the like for forming a thin film on the substrate 10. Referring to FIG. 1, the spray unit 120 of the present embodiment may be disposed above the support 110 to spray a gas and the like for forming a thin film onto the one surface 12 of the substrate 10. The thin film deposition apparatus 100 of the present embodiment may further include a chamber 105 having the support 110 and the spray unit 120 installed therein and being configured to discharge the gas therein. The spray unit 120 may include a first spray section 130 and a second spray section 140, which are arranged along the first direction DR1.

The first spray section 130 is configured to spray and exhaust a source gas 20 onto the one surface 12 of the substrate 10. Referring to FIGS. 1 to 3, the first spray section 130 of the embodiment may include a first spray nozzle 132 configured to spray the source gas 20 and an exhaust pipe 134 configured to discharge the source gas 20 sprayed from the first spray nozzle 132. For example, the first spray nozzle 132 may be configured to spray the source gas 20 onto the one surface 12 of the substrate 10, by having a spray opening disposed to face the one surface 12 of the substrate 10. Moreover, the exhaust pipe 134 may be disposed adjacent to the first spray nozzle 132. Accordingly, the source gas 20 may be adsorbed to the one surface 12 of the substrate 10 to which the first spray nozzle 132 is oriented, and the remaining gas not adsorbed to the substrate 10 may be discharged through the exhaust pipe 134. The source gas 20 may be a gas containing a metal precursor. For example, the source gas 20 may include Di-isopropylamino Silane (DIPAS), Trimethylaluminum (TMA), or the like.

The second spray section 140 is configured to spray a reaction gas 30 onto the one surface 12 of the substrate 10 and to form a plasma. Referring to FIGS. 1 to 3, the second spray section 140 of the present embodiment may include a second spray nozzle 142 configured to spray the reaction gas 30 and a plasma electrode 144 configured to form the plasma. For example, the second spray nozzle 142 may be configured to spray the reaction gas 30 onto the one surface 12 of the substrate 10, by having a spray opening disposed to face the one surface 12 of the substrate 10. The plasma electrode 144 is configured to form a plasma that activates the reactivity of the reaction gas 30 on the one surface 12 of the substrate 10 opposite to the plasma electrode 144. Accordingly, the reaction gas 30 activated by the plasma may react with the source gas 20 on the one surface 12 of the substrate 10, to which the second spray nozzle 142 is oriented, to form a thin film, and the remaining, unreacted reaction gas 30 may be discharged without reacting. In such a case, the reaction gas 30 may be a non-metallic reaction gas that reacts with metal precursors. For example, the reaction gas 30 may include O₂. N₂O, or the like.

Particularly, in an embodiment of the present disclosure, the reaction gas 30 sprayed from the second spray section 140 can flow over the one surface 12 of the substrate 10 and be exhausted through the first spray section 130.

Referring to FIGS. 2 and 3, the reaction gas 30 sprayed from the second spray section 140 may flow over the one surface 12 of the substrate 10 and flow into the first spray section 130, and the reaction gas 30 flowed in from the second spray section 140 may be discharged through the exhaust pipe 134 of the first spray section 130. In such a case, the reaction gas 30 flowing over the one surface 12 of the substrate 10 may remove the source gas 20 remaining on the substrate 10 without being adsorbed onto the one surface 12 from the substrate 12. That is, between the second spray section 140 and the first spray section 130, the reaction gas 30 may perform a purging action of removing unnecessary source gas 20 from the one surface 12 of the substrate 10. Since the reaction gas 30 does not come into contact with the plasma between the second spray section 140 and the first spray section 130 and thus is not activated, the reaction gas 30 may not react with the source gas 20.

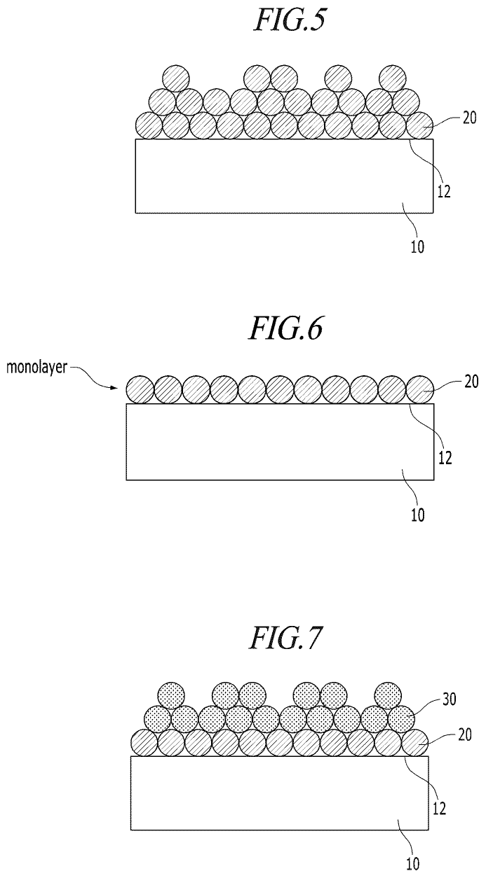

FIGS. 4 to 8 are diagrams illustrating how a thin film is formed by the thin film deposition apparatus 100 according to one embodiment of the present disclosure. FIG. 4 shows that, when the first spray section 130 and the second spray section 140 are repeatedly arranged along the first direction DR1, a source region S, a first purge region P1, a reaction region R, and a second purge region P2 are repeatedly formed.

Referring to FIGS. 4 and 5, the source region S, to which the source gas 20 is adsorbed, may be formed on the one surface 12 of the substrate 10 to which the first spray nozzle 132 is oriented. In the source region S, atoms of the source gas 20 may be adsorbed as a monolayer on the one surface 12 of the substrate 10. In such a case, some of the source gas 20 may remain above the monolayer.

Referring to FIGS. 4 and 6, the first purge region P1 may be formed between the first spray section 130 and the second spray section 140, and the reaction gas 30 flowing over the one surface 12 of the substrate 10 may perform a purging action of removing the source gas 20 remaining above the monolayer. Accordingly, the one surface 12 of the substrate 10 may become a state where the remaining source gas 20 above the monolayer is removed, leaving only the monolayer attached.

Referring to FIGS. 4 and 7, on the one surface 12 of the substrate 10, where the second spray nozzle 142 is oriented and the plasma is formed, the reaction region R, in which the monolayer of the source gas 20 reacts with the reaction gas 30 to form a thin film, may be formed. In such a case, the remaining reaction gas 30, which has not reacted in the reaction region R, may move along the one surface 12 of the substrate 10 toward the first spray section 130, in which the source region S is located. Moreover, the reaction gas 30 that did not participate in the reaction may remain and be attached above the thin film.

Referring to FIGS. 4 and 8, the second purge region P2 may be formed between the second spray section 140 and the next first spray section 130, and the reaction gas 30 flowing over the one surface 12 of the substrate 10 may perform a purging action of removing the reaction gas 30 remaining above the thin film. Accordingly, the thin film formed on the one surface 12 of the substrate 10 may become a state where the remaining reaction gas 30 above the thin film is removed, leaving only the thin film attached.

Therefore, according to the present disclosure, since the reaction gas 30 performs the purging action of pushing out and displacing the source gas 20, it become possible not only to skip separate configurations required for purging and air curtains from the thin film deposition apparatus 100 but also to skip any additional exhaust configurations for discharging the reaction gas 30.

Furthermore, since the reaction gas 30 is structured to push and purge the source gas 20 to the source region S, the path through which the source gas 20 is flowed into the reaction region R may be fundamentally blocked.

The spray unit 120 of the present embodiment may further include a partition wall 122 that separates the first spray section 130 from the second spray section 140. Referring to FIGS. 1 to 4, the partition wall 122 of the present embodiment is configured to block direct movement of gas between the first spray section 130 and the second spray section 140 within the spray unit 120. Accordingly, the reaction gas 30 sprayed from the second spray section 140 may be sprayed onto the one surface 12 of the substrate 10, which is outside the spray unit 120, and then may move through the gap G between the one surface 12 of the substrate 10 and the partition wall 122 to the first spray section 130 before being exhausted through the first spray section 130 (See FIG. 3). Therefore, the reaction gas 30 sprayed from the second spray section 140 may perform a purging action in the gap G between the one surface 12 of the substrate 10 and the partition wall 122.

The width of the gap G between the one surface 12 of the substrate 10 and the partition wall 122 may be set to enable the purging action to be carried out effectively by the reaction gas 30. For example, the width of the gap G between the one surface 12 of the substrate 10 and the partition wall 122 may be narrower than the distance between the one surface 12 of the substrate 10 and the second spray nozzle 142. Accordingly, as the reaction gas 30 flows through the gap G between the one surface 12 of the substrate 10 and the partition wall 122, the flow speed of the reaction gas 30 increases, and the gas remaining in the purge region may be effectively removed at a fast flow speed.

Moreover, the partition wall 122 may serve to retain the plasma within the second spray section 140. That is, the partition wall 122 may block the plasma from leaking outside beyond the second spray section 140 to ensure that the reaction between the reaction gas 30 and the source gas 20 activated by the plasma occurs only in the reaction region in front of the second spray section 140.

In such a case, the spray unit 120 of the present embodiment may further include a spacing adjustment mechanism 125 configured to adjust the distance between the spray unit 120 and the substrate 10. By adjusting the distance between the spray unit 120 and the substrate 10 using the spacing adjustment mechanism 125 in the present embodiment, the width of the gap G between the one surface 12 of the substrate 10 and the partition wall 122 may be adjusted. Referring to FIG. 1, the spacing adjustment mechanism 125 of the present embodiment may be configured to advance and retract the spray unit 120 in the third direction DR3, which is oriented toward the one surface 12 of the substrate 10. In an embodiment, the spacing adjustment mechanism 125 may include a motor.

Additionally, the spacing adjustment mechanism 125 of the present embodiment may be provided with a tilting function to incline the spray unit 120 relative to the substrate 10. For example, the spacing adjustment mechanisms 125 in the present embodiment may be provided in plurality, and by having the heights set differently by the plurality of spacing adjustment mechanisms 125, the spray unit 120 may be tilted based on the third direction DR3. Accordingly, by adjusting the plurality of spacing adjustment mechanisms 125, the width of the gap G between the one surface 12 of the substrate 10 and the partition wall 122 may be readily adjusted.

In the present embodiment, a plurality of the first spray sections 130 and a plurality of the second spray sections 140 may be alternately arranged along the first direction DR1. For example, the second spray section 140 may be provided in at least one pair, and the first spray section 130 may be disposed between the one pair of second spray sections 140.

In such a case, the substrate 10 may be transported in the first direction DR1. Accordingly, the one surface 12 of the substrate 10 may sequentially flow through the source region S, the first purge region P1, the reaction region R, and the second purge region P2 formed by the spray unit 120, and a thin film may be formed on the one surface 12 of the substrate 10.

Alternatively, the spray unit 120 may be moved in the first direction DR1 (along the first direction opposite to the transport direction of the substrate 10). As the spray unit 120 is moved relative to the substrate 10, the source region S, the first purge region P1, the reaction region R, and the second purge region P2 may be sequentially formed on the one surface 12 of the substrate 10, and the thin film may be formed.

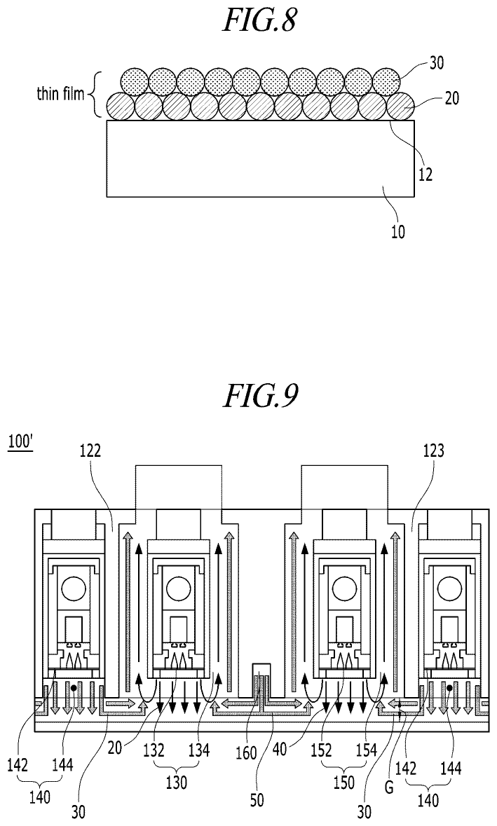

FIG. 9 is a diagram illustratively showing a thin film deposition apparatus 100′ according to another embodiment of the present disclosure. Referring to FIG. 9, the thin film deposition apparatus 100′ of the present embodiment differs from the above-described embodiment in that the spray unit 120 further includes a third spray section 150 configured to spray a doping gas 40. The doping gas 40 is a gas additionally supplied to the one surface 12 of the substrate 10, to which the source gas 20 is adsorbed, in order to impart additional properties to the thin film.

The spray unit 120 in the present embodiment may further include the third spray section 150 disposed between the first spray section 130 and the second spray section 140 described above. The third spray section 150 may be configured to spray and exhaust the doping gas 40 onto the one surface 12 of the substrate 10. Accordingly, the reaction gas 30 sprayed from the second spray section 140 may flow over the one surface 12 of the substrate 10 and be exhausted through the third spray section 150.

The third spray section 150 in the present embodiment may include a third spray nozzle 152 configured to spray the doping gas 40 and an exhaust pipe 154 configured to discharge the doping gas 40 sprayed from the third spray nozzle 152. For example, the third spray nozzle 152 may be arranged with a spray opening thereof facing the one surface 12 of the substrate 10 to spray the doping gas 40 onto the one surface 12 of the substrate 10. Moreover, the exhaust pipe 154 may be disposed adjacent to the third spray nozzle 152. Accordingly, the remaining doping gas 40 may be discharged through the exhaust pipe 154. Moreover, the reaction gas 30 sprayed from the second spray section 140 may also flow over the one surface 12 of the substrate 10 to be flowed into the third spray section 150 and discharged through the exhaust pipe 154.

The spray unit 120 in the present embodiment may further include a partition wall 123 that separates the third spray section 150 from the second spray section 140. The partition wall 123 separating the third spray section 150 from the second spray section 140 may function in a similar or identical manner to the partition wall 122 separating the first spray section 130 from the second spray section 140 as described in the above-described embodiment.

Referring to FIG. 9, the partition wall 123 separating the third spray section 150 from the second spray section 140 is configured to block the direct movement of gas between the third spray section 150 and the second spray section 140 within the spray unit 120. Accordingly, the reaction gas 30 sprayed from the second spray section 140 may be sprayed onto the one surface 12 of the substrate 10, which is outside the spray unit 120, and then moved through the gap G between the one surface 12 of the substrate 10 and the partition wall 123 to the third spray section 150 before being exhausted. Therefore, the reaction gas 30 sprayed from the second spray section 140 may perform a purging action in the gap G between the one surface 12 of the substrate 10 and the partition wall 123.

The width of the gap G between the one surface 12 of the substrate 10 and the partition wall 123 may be set to enable the purging action to be carried out effectively by the reaction gas 30. For example, the width of the gap G between the one surface 12 of the substrate 10 and the partition wall 123 may be narrower than the distance between the one surface 12 of the substrate 10 and the third spray nozzle 152. Accordingly, the flow speed of the reaction gas 30 increases as the reaction gas 30 flows through the gap G between the one surface 12 of the substrate 10 and the partition wall 123, and the remaining gas may be effectively removed at a fast flow speed.

In the present embodiment, the spray unit 120 may further include a fourth spray section 160 disposed between the first spray section 130 and the third spray section 150 and configured to spray a purge gas 50 onto the one surface 12 of the substrate 10. That is, in the present embodiment, the fourth spray section 160 for separate purging may be additionally installed between the first spray section 130 and the third spray section 150. The fourth spray section 160 may include a fourth nozzle (not shown) configured to spray the purge gas 50.

The purge gas 50 sprayed from the fourth spray section 160 may flow over the one surface 12 of the substrate 10 and be exhausted through the first spray section 130 and the third spray section 150. The purge gas 50 may be discharged through the exhaust pipes 134, 154 of the first spray section 130 and the third spray section 150, respectively. Moreover, the reaction gas 30 sprayed from the second spray section 140 and the purge gas 50 sprayed from the fourth spray section 160 may be the same gas.

In the present embodiment, the first spray section 130, the third spray section 150, and the fourth spray section 160 may be arranged between a pair of second spray sections 140. In such a case, since the first spray section 130 is disposed between the second spray section 140 and the fourth spray section 160, the reaction gas 30 sprayed from the second spray section 140 and the purge gas 50 sprayed from the fourth spray section 160 may be discharged through the first spray section 130.

Moreover, since the third spray section 150 is disposed between the second spray section 140 and the fourth spray section 160, the reaction gas 30 sprayed from the second spray section 140 and the purge gas 50 sprayed from the fourth spray section 160 may be discharged through the third spray section 150.

Similar to the above-described embodiment, the spray unit 120 of the present embodiment may also further include a spacing adjustment mechanism 125 configured to adjust the distance from the substrate 10. By adjusting the distance between the spray unit 120 and the substrate 10 using the spacing adjustment mechanism 125 in the present embodiment, the width of the gap G between the one surface 12 of the substrate 10 and the partition wall 122 may be adjusted. The spacing adjustment mechanism 125 may be configured to advance and retract the spray unit 120 in the third direction, which is oriented toward the one surface 12 of the substrate 10.

Additionally, the spacing adjustment mechanism 125 of the present embodiment may be provided with a tilting function to incline the spray unit 120 relative to the substrate 10. For example, the spacing adjustment mechanism 125 of the present embodiment may be provided in plurality, and by having the heights set differently by the plurality of spacing adjustment mechanisms 125, the spray unit 120 may be tilted based on the third direction. Accordingly, by adjusting the plurality of spacing adjustment mechanisms 125, the distance to the one surface 12 of the substrate 10 may be readily adjusted.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

1. A thin film deposition apparatus comprising:
a support, which supports a substrate; and
a spray unit comprising a first spray section and a second spray section arranged along a first direction parallel to a major surface of the support,
wherein, in the spray unit:
the first spray section is configured to spray a source gas onto one surface of the substrate and exhaust the source gas;
the second spray section is configured to spray a reaction gas onto the one surface of the substrate and form a plasma; and
the reaction gas sprayed from the second spray section flows over the one surface of the substrate and is exhausted through the first spray section.

2. The thin film deposition apparatus according to claim 1, wherein the spray unit further comprises a partition wall separating the first spray section from the second spray section, and
wherein the reaction gas sprayed from the second spray section flows through a gap between the one surface of the substrate and the partition wall and is exhausted through the first spray section.

3. The thin film deposition apparatus according to claim 2, wherein the partition wall is configured to maintain the plasma within the second spray section.

4. The thin film deposition apparatus according to claim 2, wherein the reaction gas sprayed from the second spray section performs a purging action in the gap between the one surface of the substrate and the partition wall.

5. The thin film deposition apparatus according to claim 1, wherein the first spray section comprises:
a first spray nozzle configured to spray the source gas; and
an exhaust pipe configured to discharge the source gas sprayed from the first spray nozzle and the reaction gas flowed in from the second spray section.

6. The thin film deposition apparatus according to claim 1, wherein the support is configured to transport the substrate in the first direction.

7. The thin film deposition apparatus according to claim 1, wherein the spray unit is configured to move in the first direction.

8. The thin film deposition apparatus according to claim 1, wherein the first spray section is provided in plurality and the second spray section is provided in plurality, and
wherein the plurality of first spray sections and the plurality of second spray sections are alternately arranged along the first direction.

9. The thin film deposition apparatus according to claim 1, wherein the second spray section is provided in at least one pair, and
wherein the first spray section is disposed between the at least one pair of the second spray sections.

10. The thin film deposition apparatus according to claim 1, wherein the spray unit further comprises a spacing adjustment mechanism configured to adjust a distance from the substrate to the spray unit in a second direction normal to the major surface of the support.

11. The thin film deposition apparatus according to claim 10, wherein the spacing adjustment mechanism has a tilting function to incline the spray unit relative to the substrate.

12. A thin film deposition apparatus comprising:
a support, which supports a substrate; and
a spray unit comprising a first spray section, a third spray section, and a second spray section arranged along a direction parallel to a major surface of the support,
wherein, in the spray unit:
the first spray section is configured to spray a source gas onto one surface of the substrate and exhaust the source gas;
the second spray section is configured to spray a reaction gas onto the one surface of the substrate and form a plasma;
the third spray section is disposed between the first spray section and the second spray section and is configured to spray a doping gas onto the one surface of the substrate and exhaust the doping gas; and
the reaction gas sprayed from the second spray section flows over the one surface of the substrate and is exhausted through the third spray section.

13. The thin film deposition apparatus according to claim 12, wherein the spray unit further comprises a fourth spray section disposed between the first spray section and the third spray section and configured to spray a purge gas onto the one surface of the substrate, and
wherein the purge gas sprayed from the fourth spray section flows over the one surface of the substrate and is exhausted through the first spray section and the third spray section.

14. The thin film deposition apparatus according to claim 13, wherein the reaction gas sprayed from the second spray section and the purge gas sprayed from the fourth spray section are a same gas.

15. The thin film deposition apparatus according to claim 13, wherein the second spray section is provided in at least one pair, and
wherein the first spray section, the third spray section, and the fourth spray section are disposed between the at least one pair of second the spray sections.

16. The thin film deposition apparatus according to claim 15, wherein, in the spray unit, the first spray section is configured to discharge the reaction gas sprayed from the second spray section and the purge gas sprayed from the fourth spray section.

17. The thin film deposition apparatus according to claim 15, wherein, in the spray unit, the third spray section is configured to discharge the reaction gas sprayed from the second spray section and the purge gas sprayed from the fourth spray section.

18. The thin film deposition apparatus according to claim 12, wherein the third spray section comprises:
a third spray nozzle configured to spray the doping gas; and
an exhaust pipe configured to discharge the doping gas sprayed from the third spray nozzle and the reaction gas flowed in from the second spray section.

19. The thin film deposition apparatus according to claim 12, wherein the spray unit further comprises a partition wall separating the third spray section from the second spray section, and
wherein the reaction gas sprayed from the second spray section flows through a gap between the one surface of the substrate and the partition wall and is exhausted through the third spray section.

20. The thin film deposition apparatus according to claim 19, wherein the reaction gas sprayed from the second spray section performs a purging action in the gap between the one surface of the substrate and the partition wall.
